(19) United States
(12) Patent Application Publication
(10) Pub. No.: US 2025/0226254 A1
(43) Pub. Date: Jul. 10, 2025

(54) PURGE SYSTEM

(71) Applicant: MURATA MACHINERY, LTD., Kyoto-shi, Kyoto (JP)

(72) Inventors: Yoshiya WADA, Ise-shi (JP); Yasuhisa ITO, Inuyama-shi (JP)

(21) Appl. No.: 18/700,352

(22) PCT Filed: Sep. 12, 2022
(86) PCT No.: PCT/JP2022/034096

§ 371 Date: Apr. 11, 2024

(30) Foreign Application Priority Data
Oct. 21, 2021 (JP) 2021-172598

(51) Int. Cl. H01L 21/673; H01L 21/677

(52) U.S. Cl. CPC H01L 21/67393; H01L 21/67778

(57) ABSTRACT

A purge system includes a main pipe, a feed controller configured to control a flow rate or a pressure of purge gas flowing through the main pipe, feed paths between respective placing sections and the main pipe, at least one open/close valve correspondingly provided to each of the placing sections and configured to switch the flow of purge gas in the feed paths, and a controller configured to control an open/close state of the open/close valve and control the feed controller based on open/close states of all of the open/close valves provided to the main pipe.

### BACKGROUND OF THE INVENTION

### 1. Field of the Invention

This disclosure relates to purge systems.

### 2. Description of the Related Art

Conventionally, in a storage facility including a plurality of storage sections for storing containers, a facility configured to feed inert gas to containers to be stored in the respective storage sections is known. For example, a storage facility described in Japanese Patent No. 6856015 is provided with two (a plurality of) main pipes for a plurality of storage sections. Each of the two main pipes is connected to each of the storage sections by branch pipes. A first switching valve is provided in a first branch pipe between a first main pipe and each of the storage sections, and a second switching valve is provided in a second branch pipe between a second main pipe and each of the storage sections. The first switching valve is opened and the second switching valve is closed for a storage section that requires initial purging (first purging process). The first switching valve is closed and the second switching valve is opened for a storage section that requires maintenance purging (second purging process).

In the facility described in Japanese Patent No. 6856015, a first flow rate control device provided in the first main pipe controls a flow rate of inert gas in the first main pipe according to the number of the first branch pipes in which inert gas flow is not blocked by the first switching valve (number of pipes in which the initial purging is performed). The second flow rate control device provided in the second main pipe controls a flow rate of inert gas in the second main pipe according to the number of second branch pipes in which inert gas flow is not blocked by the second switching valve (the number of pipes in which the maintenance purging is performed).

### SUMMARY OF THE INVENTION

The conventional storage facility described above requires a plurality of the flow rate control devices corresponding to a plurality of the main pipes in order to perform individual control of a purge gas feed rate.

The present disclosure describes purge systems each capable of performing individual control of a purge gas feed rate of each placing section with a bare minimum of controllers.

An aspect of an example embodiment of the present disclosure is a purge system including a plurality of placing sections, a plurality of nozzles each configured to feed purge gas to a container at each of the placing sections, a main pipe through which purge gas flows, a feed controller connected to the main pipe and configured to control a flow rate or a pressure of the purge gas flowing through the main pipe, a plurality of feed paths each provided between a respective one of the plurality of placing sections and the main pipe, the plurality of feed paths each including at least one feed tube, all of the feed tubes of the feed paths being connected to the plurality of nozzles, at least one open/close valve correspondingly provided to each of the placing sections and configured to switch flow of the purge gas in the feed paths, and a controller configured to control an open/close state of the at least one open/close valve and control the feed controller based on open/close states of all the open/close valves provided to the main pipe, wherein the controller is further configured to adjust the flow rate of the purge gas supplied to the plurality of nozzles at each of the placing sections to a selected one among multiple predefined supply flow rates.

In this purge system, the controller controls the open/close state of the open/close valve, thereby switching the purge gas flow in the feed paths. For example, a feed flow rate of the purge gas to the nozzle of each of the placing sections can be varied by allowing the purge gas to flow through only some or all of the feed paths. The feed controller is controlled by the controller, thereby controlling the flow rate or pressure of the purge gas flowing through the main pipe based on the open/close states of all the open/close valves provided for the main pipe. With this configuration, the individual control of the purge gas feed rate can be performed for each of the plurality of placing sections belonging to one main pipe by only one feed controller.

The feed tube may be provided with an orifice to allow purge gas to flow through at a certain flow rate with the pressure of the purge gas (differential pressure before and behind the orifice). Thus, flow rate control can be performed more reliably and easily.

In at least one of the feed paths, the at least one feed tube may include a plurality of branch tubes connected in parallel, and each of the branch tubes may include the orifice. A certain flow rate of purge gas flows through one orifice, i.e., per branch tube. At least one feed path includes a plurality of the branch tubes and a plurality of the orifices, and thus a desired flow rate control can be performed easily.

Orifices identical to the orifice may be provided for all the feed tubes of the feed paths. In this case, by increasing the number of feed tubes, that is, the number of orifices, the flow rate of purge gas can be varied by a multiple corresponding to the number of orifices.

The feed paths may include a first feed path and a second feed path, and a first orifice provided in at least one first feed tube serving as the feed tube of the first feed path and a second orifice provided in at least one second feed tube serving as the feed tube of the second feed path may be different from each other, so that the flow rate of the purge gas flowing through the first feed tube may be different from the flow rate of the purge gas flowing through the second feed tube. In this case, the flow rate can be freely set (adjusted) by setting types and the number of orifices as appropriate.

The feed controller may be a flow rate controller configured to control a flow rate of purge gas flowing through the main pipe. In this case, the purge gas feed rate with respect to each of the placing sections can be controlled reliably and easily.

With the purge systems according to example embodiments of the present disclosure, the individual control of the purge gas feed rate can be performed for each of the plurality of placing sections belonging to one main pipe by only one feed controller.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a side view illustrating a purge stocker to which a purge system according to a first example embodiment of the present invention is applied.

FIG. 2 is a schematic configuration diagram illustrating a placing section, nozzles, and a feed tube in the purge stocker of FIG. 1.

FIG. 3 is a piping system diagram of the purge system according to the first example embodiment of the present invention.

FIGS. 4A and 4B are views each illustrating a first purging process and a second purging process with respect to one placing section (nozzle).

FIG. 5 is a block diagram illustrating a control configuration of a flow rate controller and a plurality of open/close valves in the purge system.

FIG. 6 is a flow diagram illustrating a process in a controller of FIG. 5.

FIGS. 7A to 7C are diagrams each illustrating a modification of a plurality of feed paths and open/close valves.

FIG. 8 is a piping system diagram of a purge system according to a second example embodiment of the present invention.

FIG. 9 is a piping system diagram illustrating a purge system according to a modification of the second example embodiment of the present invention.

FIG. 10 is a diagram illustrating an overall structure of a storage shelf to which the purge system according to the present disclosure is applied.

FIG. 11 is a perspective view illustrating placing sections and nozzles in the storage shelf, and an overhead transport vehicle in FIG. 10.

### DETAILED DESCRIPTION OF THE EXAMPLE EMBODIMENTS

Example embodiments of the present invention will be described below with reference to the drawings. In description of the drawings, like numerals indicate like components, and overlapping description will be omitted.

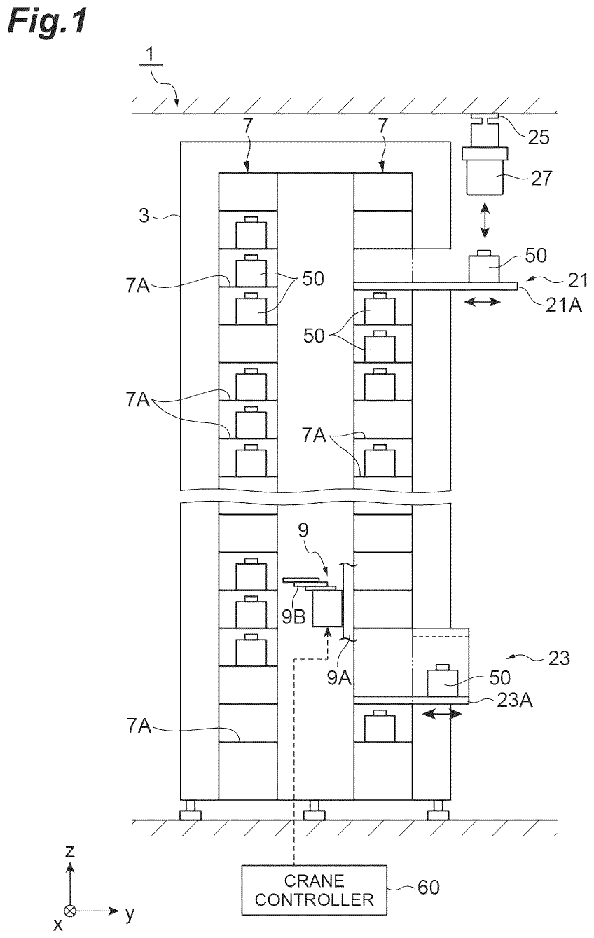

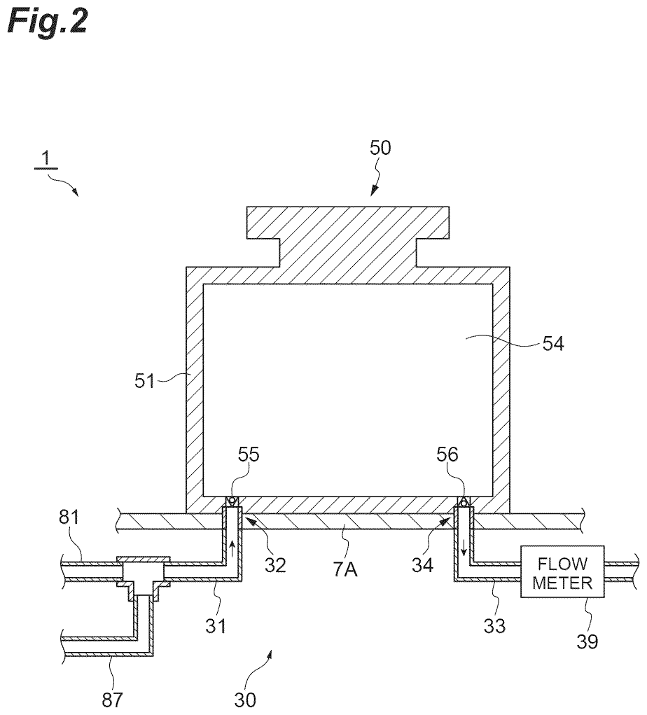

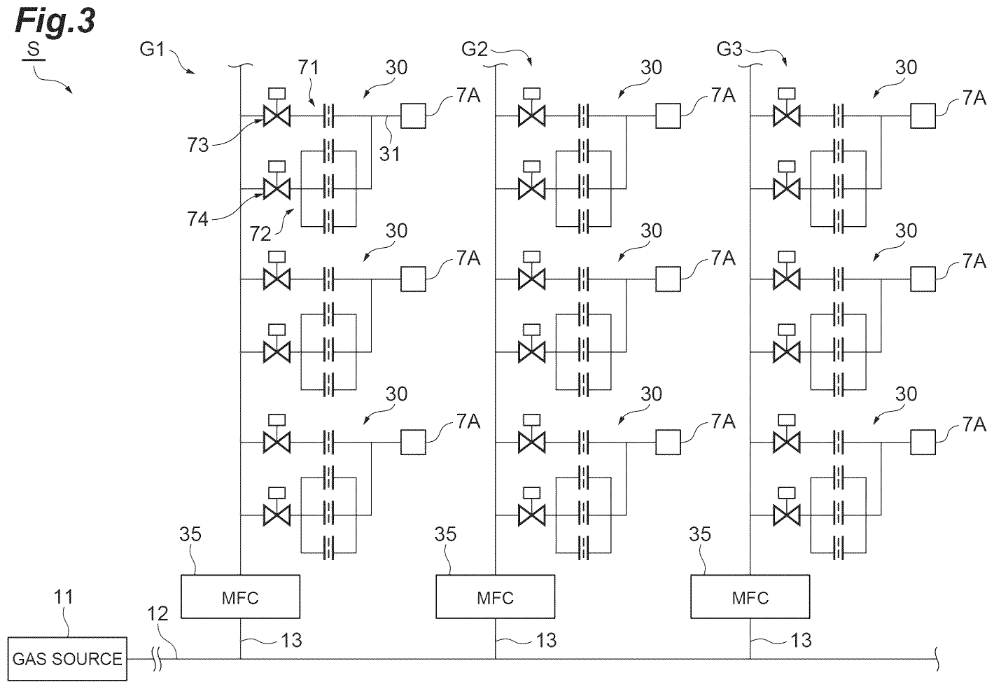

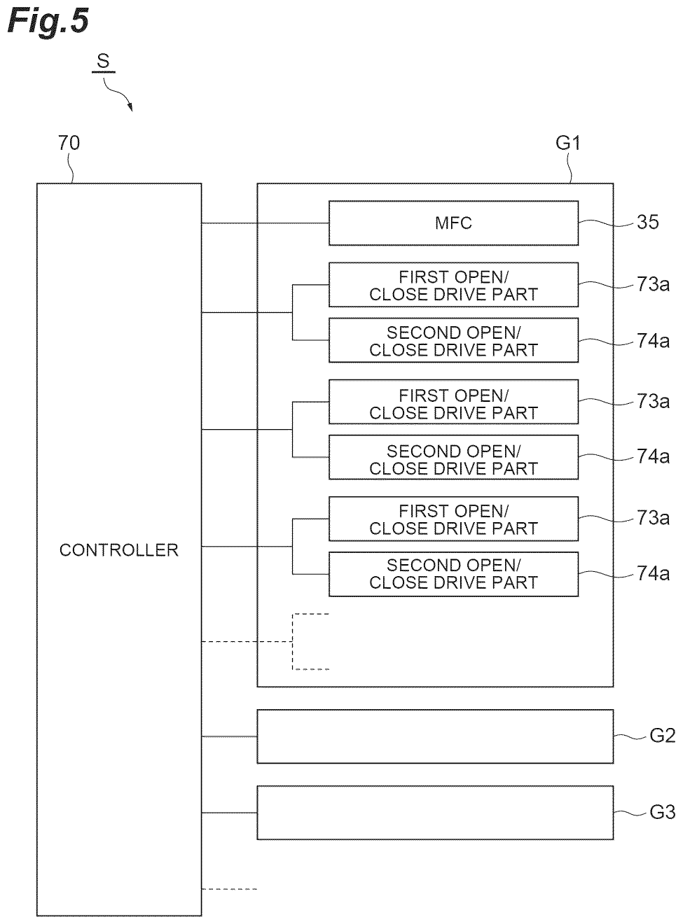

A purge system S (see FIGS. 3 and 5) according to the present example embodiment is applied, for example, to a purge stocker 1 (FIGS. 1 and 2). Although the purge system S applied to the purge stocker 1 is mainly described below, purge systems S according to example embodiments of the present disclosure are applicable to any purge device including a plurality of placing sections at which containers are placed and nozzles that feed purge gas into the containers placed in the respective placing sections.

As illustrated in FIGS. 1 and 2, the purge stocker 1 has a function of a purge device configured to fill the inside of a container 50 with purge gas (purging process), in addition to a function as a storage container configured to store a plurality of the containers 50. The container 50 is a storage container such as a FOUP, a SMIF pod, a reticle pod, or the like, in which an object stored such as a semiconductor wafer, a glass substrate, or the like is stored. For example, inert gas such as nitrogen gas or air is used as a purge gas. The purge stocker 1 is provided, for example, in a clean room. As illustrated in FIG. 1, the purge stocker 1 mainly includes a partition 3, a rack 7, a crane 9, an overhead hoist transfer (OHT) port 21, and a manual port 23.

The partition 3 is a cover plate of the purge stocker 1. In the partition 3, a storage area to store the container 50 is provided. The rack 7 is configured to store the container 50, and one or a plurality of rows (two rows in this example) of the racks 7 are provided in the storage area. The racks 7 each extend in a X direction that is a horizontal direction and are disposed parallel or substantially parallel with each other such that adjacent two racks 7, 7 are opposite to each other in a Y direction that is a horizontal direction. Each of the racks 7 includes a plurality of placing sections 7A formed therein, in which the container 50 is placed and stored along the X direction and the Z direction that is a vertical direction. The placing section 7A is also referred to as a purge shelf. A plurality of the placing sections 7A are disposed in line along the Z direction and are also disposed in line along the X direction.

The crane 9 is a transport device configured to take in and out the container 50 to and from the placing section 7A and also move the container 50 between the placing section 7A and the OHT port 21 and the manual port 23. The crane 9 is disposed in an area sandwiched by the opposing racks 7, 7. The crane 9 moves on a traveling rail (not illustrated) disposed on a floor surface along the X direction in which the rack 7 extend. The crane 9 includes a guide rail 9A that extends in the Z direction that is a vertical direction and a load bed 9B that can be raised and lowered along the guide rail 9A. Transport of the container 50 by the crane 9 is controlled by a crane controller 60. The crane controller 60 is an electronic control unit (ECU) including a central processing unit (CPU), a read only memory (ROM), a random access memory (RAM), and the like.

Loading in and unloading of the container 50 to and from the purge stocker 1 are performed through the OHT port 21 and the manual port 23. The OHT port 21 is a structure where the container 50 is passed between an overhead transport vehicle (OHT) 27 traveling on a traveling rail 25 installed on a ceiling, and the purge stocker 1. The OHT port 21 includes a conveyor 21A configured to transport the containers 50. The manual port 23 is a structure where the container 50 is passed between a worker and the purge stocker 1. The manual port 23 includes a conveyor 23A configured to transport the containers 50.

As illustrated in FIG. 2, a container body 51 has a rectangular or substantially rectangular box shape, for example. The container 50 includes the container body 51 and a removable lid (not illustrated). In the container 50, a sealed space 54 is defined by the container body 51 and the lid member. A plurality of semiconductor wafers (not illustrated), for example, are stored in the sealed space 54.

The placing section 7A is provided with a purge device 30 configured to feed purge gas to the sealed space 54 inside the container 50 placed on the placing section 7A. A bottom wall of the container 50 includes a feed port 55 and a discharge port 56. A predetermined flow rate of purge gas is fed to the purge device 30 from a gas source 11 by the purge system S, which will be described below (see FIG. 3). The purge device 30 includes a feed tube end 31, an injection nozzle (nozzle) 32, a discharge nozzle 34, and a discharge pipe 33. The feed port 55 of the container 50 is connectible to the injection nozzle 32 provided at the outlet end of the feed tube end 31. The discharge port 56 is connectible to the discharge nozzle 34 at an inlet end of the discharge pipe 33. When the container 50 is placed on the placing section 7A, the injection nozzle 32 is connected to the feed port 55 and the discharge pipe 33 is connected to the discharge port 56. In this connection status, purge gas is fed to the sealed space 54 of the container 50 through the injection nozzle 32 and the feed port 55, and the purge gas in the sealed space 54 of the container 50 is aspirated through the discharge port 56 and the discharge nozzle 34. A flow meter 39 may be provided in the discharge pipe 33. The flow meter 39 measures a flow rate of purge gas flowing through the discharge pipe 33 and provides information to determine a purge status.

The discharge nozzle 34, the discharge pipe 33, and the flow meter 39 may be omitted from the purge device 30. In that case, the purge gas is discharged to the outside of the container 50 through the discharge port 56.

With reference to FIGS. 3 to 5, the purge system S according to the present example embodiment is then described. The purge system S includes a plurality of the placing sections 7A and the purge device 30 configured to feed purge gas to the containers 50 placed on each of the placing sections 7A. The purge system S controls feed of the purge gas in a plurality of the purge devices 30. As described above, each of the purge devices 30 includes one injection nozzle 32. The purge system S can perform individual control of the purge gas feed rate for each of the injection nozzles 32.

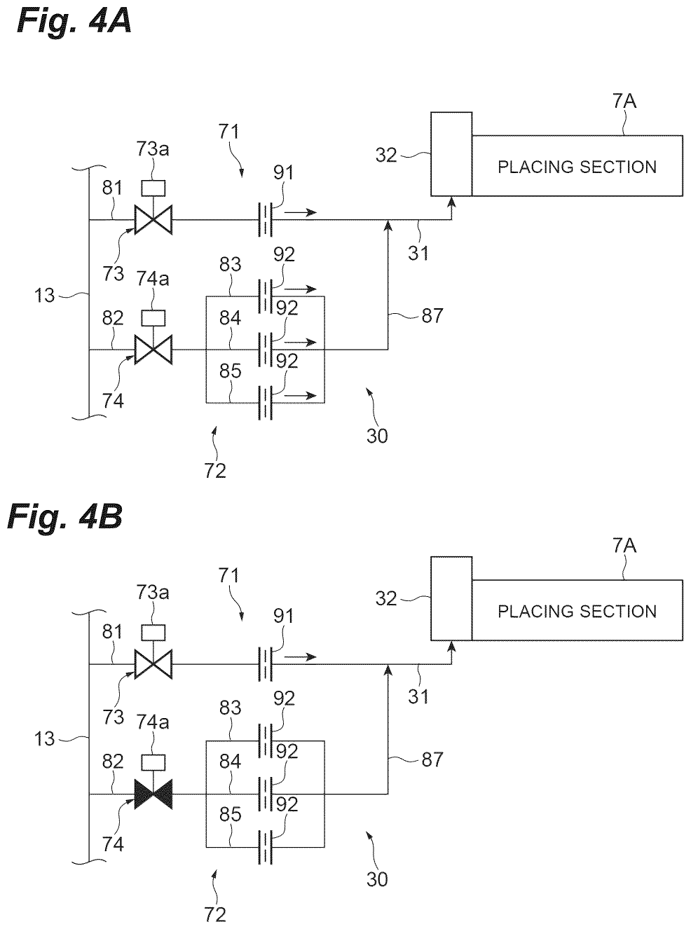

As illustrated in FIGS. 3 and 4, the purge system S includes one gas source 11 in which purge gas is stored, one header pipe 12 connected to the gas source 11, and a plurality of main pipes 13 branching from the header pipe 12. The gas source 11 is a tank configured to store purge gas. Purge gas flows through the header pipe 12 and the main pipe 13. The purge system S further includes a mass flow controller (MFC) (feed controller) 35 connected to each of the main pipes 13 and configured to control the flow rate of the purge gas through the main pipe 13. The MFC 35 is a flow rate controller configured to measure a mass flow rate of the purge gas flowing through the main pipe 13 and perform flow rate control. In the purge system S, the flow rate control in the MFC 35 is performed by a controller 70, which will be described below.

In the purge system S, the plurality of placing sections 7A and the plurality of injection nozzles 32 are connected by branching from one main pipe 13. The plurality of placing sections 7A and the plurality of purge devices 30 connected to the one main pipe 13 define one group. In other words, the purge system S includes a plurality of the groups. Specifically, the purge system S includes a first group G1, a second group G2, and a third group G3. The number of groups included in the purge system S may be two or more (plural) or only one. The number of groups may be equal to the number of the main pipes 13.

In the plurality of groups, the purge device 30 and the placing section 7A have similar configurations. Each of the groups has a similar form of connection from the main pipe 13 to the corresponding purge device 30 (see FIG. 3). In the groups, the number of the placing sections 7A (i.e., the number of the purge devices 30 or the number of injection nozzles 32) belonging to each of the groups may be different. Even in a case where the number of the placing sections 7A belonging to each group is different, the purge system S enables individual control for each of the injection nozzles 32 belonging to all the groups. With reference to FIGS. 4A and 4B, one purge device 30 of the plurality of purge devices 30 belonging to the first group G1 will be described.

As illustrated in FIG. 4A, various configurations according to individual control of purge gas are provided between the one main pipe 13 and the placing section 7A (injection nozzle 32). For example, two feed paths are provided between each of the placing sections 7A and the main pipe 13. The purge device 30 includes a first feed path 71 branching from the main pipe 13 and a second feed path 72 branching from the main pipe 13. The first feed path 71 includes one first feed tube 81. The second feed path 72 includes one second feed tube 82, and a first branch tube 83, a second branch tube 84, and a third branch tube 85, which further branch from the second feed tube 82 and are connected in parallel. The first branch tube 83, the second branch tube 84, and the third branch tube 85 merge at a downstream end and are connected to one second collection pipe 87. The second collection pipe 87 merges with the downstream end of the first feed tube 81 to form the feed tube end 31. The feed tube end 31 is connected to the injection nozzle 32 as described above.

In other words, in the purge device 30, all the feed tubes (the first feed tube 81, the first branch tube 83, the second branch tube 84, and the third branch tube 85) of the feed paths are connected to the injection nozzle 32. Diameters of the first feed tube 81, the first branch tube 83, the second branch tube 84, and the third branch tube 85 may all be equal, for example.

The purge device 30 includes a first solenoid valve (open/close valve) 73 and a second solenoid valve (open/close valve) 74 that are provided correspondingly to each of the placing sections 7A. The first solenoid valve 73 and the second solenoid valve 74 switch the flow of purge gas in the first feed path 71 and the second feed path 72, respectively. Specifically, the first solenoid valve 73 is provided in the first feed path 71 and switches the flow of purge gas in the first feed path 71. The second solenoid valve 74 is provided in the second feed path 72 and switches the flow of purge gas in the second feed path 72. The first solenoid valve 73 and the second solenoid valve 74 are each controlled to open and close by the controller 70. When the first solenoid valve 73 is opened, purge gas is allowed to flow in the first feed tube 81. When the first solenoid valve 73 is closed, the purge gas flow in the first feed tube 81 is shut off. When the second solenoid valve 74 is opened, the purge gas is allowed to flow in the second feed tube 82. When the second solenoid valve 74 is closed, the purge gas flow in the second feed tube 82 is shut off.

In the purge system S, a first orifice 91 is provided in the first feed tube 81. A second orifice 92 is provided in each of the first branch tube 83, the second branch tube 84, and the third branch tube 85. The first orifice 91 and the three second orifices 92 are all identical orifices, for example. Each of the first orifice 91 and second orifice 92 is an orifice plate having a hole in the center thereof, for example, the orifice plate allowing a certain flow rate of purge gas to flow in each pipe.

In the purge device 30 having the above configuration, the controller 70 drives and controls a first open/close driver 73a of the first solenoid valve 73 and a second open/close driver 74a of the second solenoid valve 74. As illustrated in FIG. 4A, when both the first solenoid valve 73 and the second solenoid valve 74 are opened, purge gas flows through both the first feed path 71 and the second feed path 72. That is, the purge gas flows through the first feed tube 81, the first branch tube 83, the second branch tube 84, and the third branch tube 85. Assuming that purge gas flows through each of the first orifice 91 and second orifice 92 at a flow rate of, for example, Q (L/min), the purge gas is fed to the injection nozzle 32 (the placing section 7A) at a flow rate of Q×4 (L/min) in a state illustrated in FIG. 4A.

On the other hand, when the first solenoid valve 73 is opened and the second solenoid valve 74 is closed, as illustrated in FIG. 4B, purge gas flows through the first feed path 71 but not through the second feed path 72. (In FIG. 4B, a close state of the second solenoid valve 74 is illustrated by a fill-in.) In other words, the purge gas flows through only the first feed tube 81. In a state illustrated in FIG. 4B, the purge gas is fed to the injection nozzle 32 (placing section 7A) at a flow rate of Q×1 (L/min). Thus, the purge device 30 can feed purge gas at a relatively large first flow rate and also can feed the purge gas at a relatively small second flow rate. The first flow rate is an integer multiple of the second flow rate.

When the first solenoid valve 73 is closed and the second solenoid valve 74 is opened, purge gas is fed to the injection nozzle 32 (the placing section 7A) at a flow rate of Q×3 (L/min).

With reference to FIG. 5, the control configuration of the flow rate controller and the plurality of open/close valves in the purge system S is described. The purge system S includes the controller 70 configured to control the open/close state of the first solenoid valve 73 and the second solenoid valve 74, and control the MFC 35 provided in each of the main pipes 13. The controller 70 is an electronic control unit (ECU) including, for example, a CPU, a ROM, a RAM, and the like. The controller 70 is installed outside the traveling space of the crane 9 in the purge stocker 1, for example. The controller 70 controls the MFC 35 based on the open/close states of all the first solenoid valves 73 and the second solenoid valves 74 in each of the main pipes 13. The controller 70 collectively controls not only the first group G1, but also the second G2 and the third group G3. The number of MFCs 35 controlled by the controller 70 is equal to the number of groups.

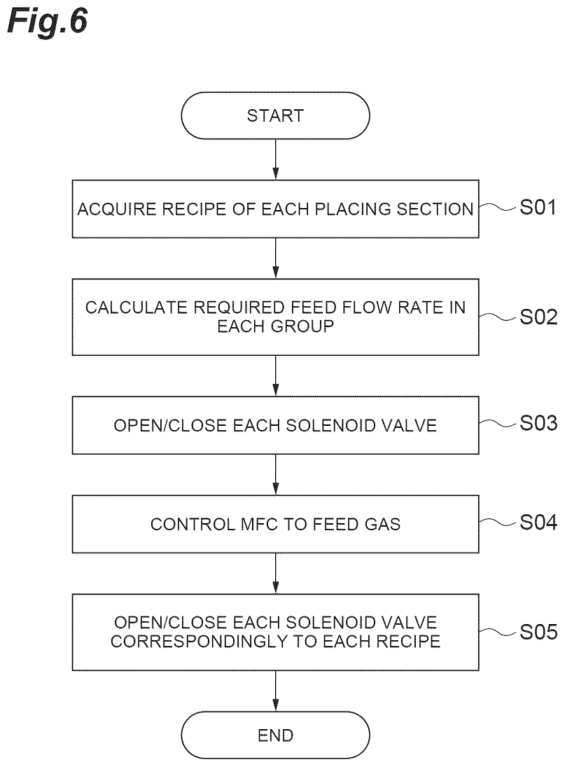

Next, with reference to FIG. 6, the process performed by the controller 70 is then described. First, the controller 70 obtains a recipe in each of the placing sections 7A (step S01). The recipe in each placing section 7A is a schedule regarding an indicated flow rate of purge gas from the time when the container 50 is placed on the placing section 7A until the container 50 is removed from the placing section 7A. The recipe may be identical in all the placing sections 7A, or may be different on a group-by-group basis, for example.

The controller 70 then calculates a required feed flow rate of purge gas in each group based on a storage state of the containers 50 in each placing section 7A (step S02). The required feed flow rate can be calculated based on the recipe obtained in step Sal. In other words, the required feed flow rate is calculated based on the open/close states of the first solenoid valve 73 and the second solenoid valve 74 in each purge device 30. Calculation of the required feed flow rate is done on a group-by-group basis for all the groups. Once a certain required feed flow rate is determined, the number of feed tubes or branch tubes (the number of orifices described above) through which purge gas flows is determined. The controller 70 then controls opening and closing each solenoid valve (step S03). The controller 70 drives and controls the first open/close driver 73a and the second open/close driver 74a (see FIG. 5), which belong to all the groups.

The controller 70 then controls each MFC 35 to feed purge gas so that the required feed flow rate calculated in step S02 is fed (step S04). After these steps S01 to S04, the controller 70 controls opens and closes each solenoid valve in response to the corresponding recipe (step S05).

Through the above series of processes, the flow rate control is performed by the controller 70.

With the purge system S according to the present example embodiment, the open/close state of the first solenoid valve 73 and the second solenoid valve 74 are controlled by the controller 70, and the flow of purge gas in the first feed path 71 and the second feed path 72 is switched. For example, the feed flow rate of purge gas to the injection nozzles 32 of each of the placing sections 7A can be varied by allowing the purge gas to flow through only some or all of the first and the second feed paths 71 and 72. The MFC 35 is controlled by the controller 70, thereby controlling the flow rate of the purge gas flowing through the main pipe 13 based on the open/close states of all the first and the second solenoid valves 73 and 74 provided for the main pipe 13. With this operation, the individual control of the purge gas feed rate can be performed with only one MFC 35 for each of the plurality of placing sections 7A belonging to the one main pipe 13.

The first orifice 91 and the second orifice 92 allow purge gas to flow through at a certain flow rate with the pressure of the purge gas (differential pressure before and behind the orifice). Thus, flow rate control can be performed more reliably and easily.

In the second feed path 72, a certain flow rate of purge gas flows through per second orifice 92, i.e., per branch tube. The second feed path 72 includes a plurality of branch tubes (the first branch tube 83, the second branch tube 84, and the third branch tube 85) and the plurality of second orifices 92, and thus a desired flow rate control can be performed easily throughout the purge device 30.

The first orifice 91 and the second orifice 92 are identical orifices. By increasing the number of feed tubes, i.e., the number of orifices, a flow rate of purge gas can be varied by a integer multiple.

With the MFC 35, the purge gas feed rate to each of the placing sections 7A can be controlled reliably and easily.

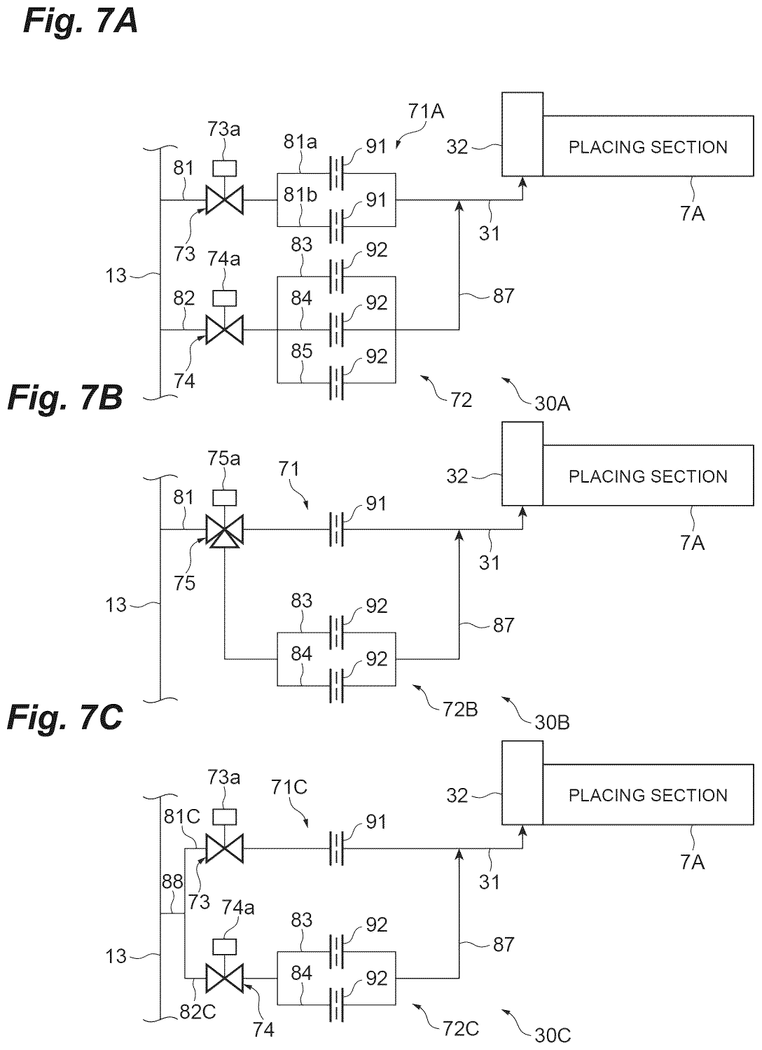

The following describes a modification and another example embodiment of the purge system S with reference to FIGS. 7A to 7C and thereafter. FIGS. 7A to 7C are diagrams each illustrating a modification regarding a plurality of feed paths and open/close valves. As illustrated in FIG. 7A, instead of the purge device 30 (see FIG. 4A, or the like), a purge device 30A may be included in which a first feed path 71A includes two branch tubes, specifically, a first branch tube 81a and a second branch tube 81b. With this purge device 30A, purge gas can flow at a flow rate of Q×2 (L/min) in the first feed path 71A and at a flow rate of Q×3 (L/min) in the second feed path 72, and thus the purge gas can flow at a flow rate of Q×5 (L/min), Q×2 (L/min), or Q×3 (L/min).

As illustrated in FIG. 7B, instead of the purge device 30 (see FIG. 4A, or the like), a purge device 30B may be included in which one electric three-way valve 75 is provided at a junction where the second feed tube 82 branches from the first feed tube 81. An open/close driver 75a of the electric three-way valve 75 is driven and controlled by the controller 70. In a second feed path 72B, two branch tubes including the first branch tube 83 and the second branch tube 84, and the two second orifices 92 may be provided. With this purge device 30B, purge gas can flow at a flow rate of Q×1 (L/min) in the first feed path 71 and at a flow rate of Q×2 (L/min) in the second feed path 72B, and thus the purge gas can flow at a rate of Q×3 (L/min), Q×1 (L/min), or Q×2 (L/min).

As illustrated in FIG. 7C, instead of the purge device 30 (see FIG. 4A, or the like), a purge device 30C may be included, the purge device 30C having a configuration in which a common branch tube 88 first branches off from the main pipe 13 and further branches into a first feed tube 81C and a second feed tube 82C. The effects of a first feed path 71C and a second feed path 72C are similar to those of the purge device 30B.

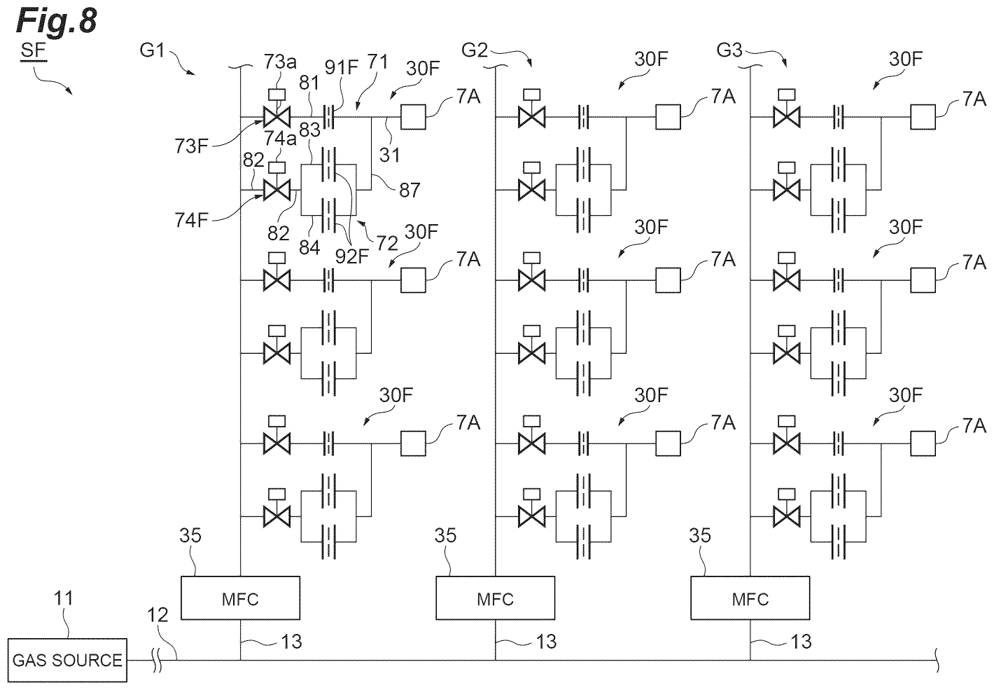

FIG. 8 is a piping system diagram of a purge system SF according to the second example embodiment. In a purge device 30F of the purge system SF, a first orifice 91F in the first feed path 71 and a second orifice 92F in the second feed path 72 are different from each other. In addition, a flow rate of purge gas flowing through the first feed tube 81 is different from a flow rate of purge gas flowing through the second feed tube 82. In the purge system SF, a configuration similar to that illustrated in FIG. 5 is provided, and the valves are controlled to open and close by the controller. The controller controls the MFC 35 based on the open/close states of all the open/close valves provided for the main pipe 13. With such a purge system SF, a flow rate can be freely set (adjusted) by setting a type and the number of orifices as appropriate.

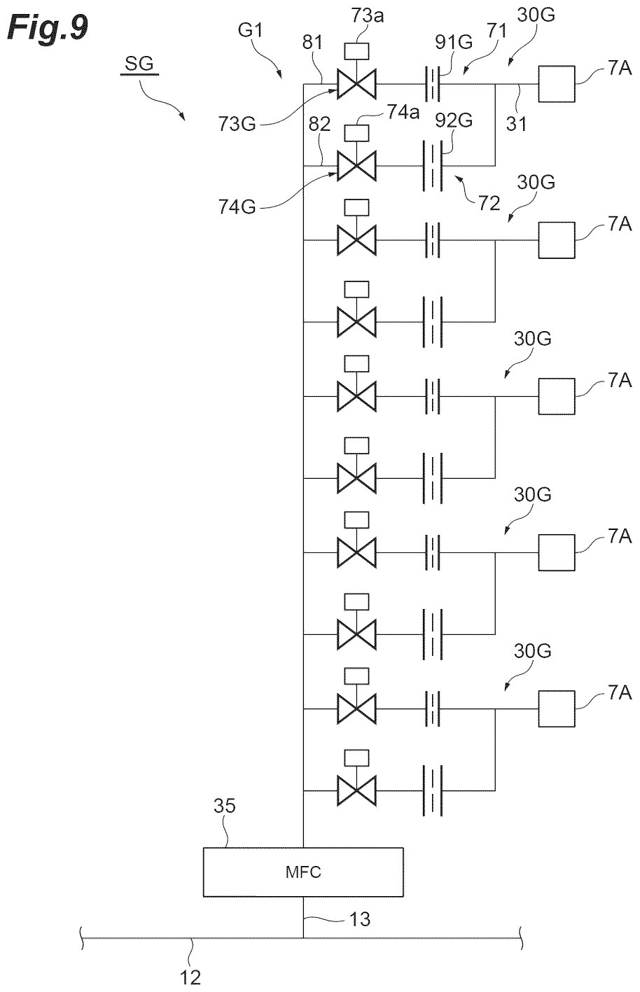

FIG. 9 is a piping system diagram of the purge system SG according to the second example embodiment. In the purge system SG, the first feed tube 81 and the second feed tube 82 do not branch from one tube, being originally two tubes independent from each other. Therefore, one first orifice 91G and one second orifice 92G are also provided for one purge device 30G. The first orifice 91G is different from the second orifice 92G and the flow rate of the purge gas flowing through the first feed tube 81 is different from the flow rate of the purge gas flowing through the second feed tube 82. In the purge system SG, a configuration similar to that illustrated in FIG. 5 is provided, and the valves are controlled to open and close by the controller. The controller controls the MFC 35 based on the open/close states of all the open/close valves provided for the main pipe 13. With such a purge system SG, the flow rate can be freely set (adjusted) by setting a type and the number of orifices as appropriate.

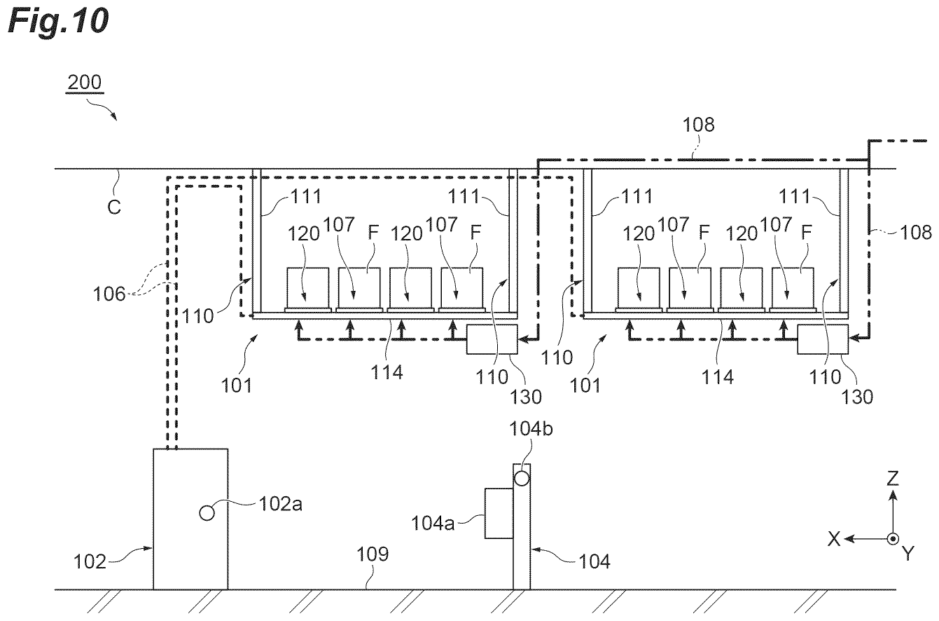

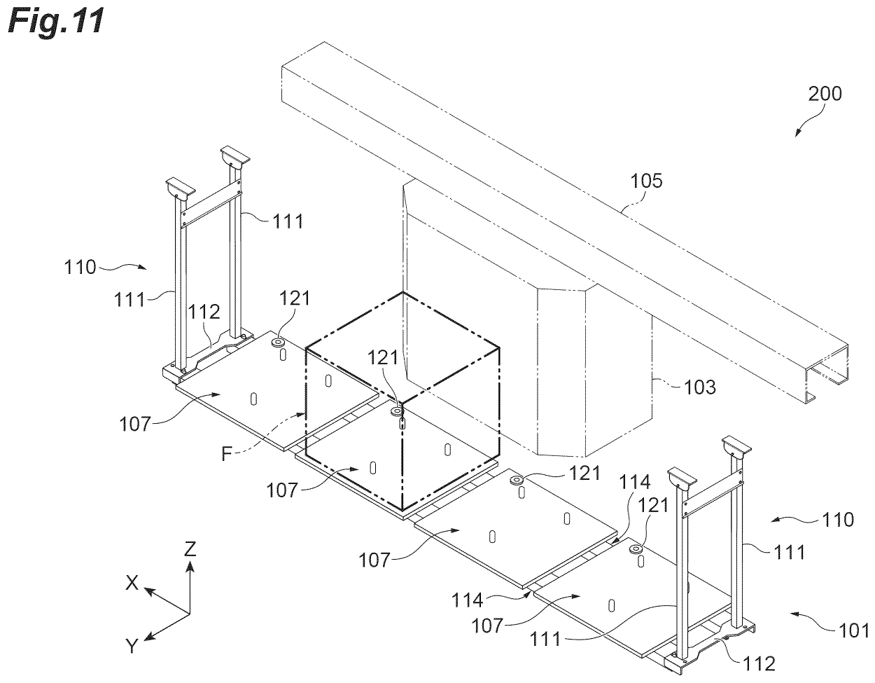

The purge system of the present disclosure can be applied to other than the purge stocker 1. For example, the purge system may be applied to a storage shelf 101, as illustrated in FIGS. 10 and 11. FIG. 10 is a diagram illustrating the overall configuration of the storage shelf 101 to which the purge system of the present disclosure is applied. FIG. 11 is a perspective view illustrating a placing section 107 and a nozzle 121 in the storage shelf 101 of FIG. 10, and an overhead transport vehicle 103

As illustrated in FIGS. 10 and 11, the storage shelf 101 is disposed along a traveling rail 105 of the overhead transport vehicle 103 of a semiconductor conveyance system 200 in a semiconductor manufacturing plant, for example. The storage shelf 101 temporarily stores a container F such as FOUP or a reticle pod. The storage shelf 101 is an overhead buffer (OHB). The storage shelf 101 may be a side track buffer (STB) disposed on a side of the traveling rail 105. A purge device 120 is attached to the storage shelf 101. The storage shelf 101 is configured to purge the inside of the container F with purge gas.

As illustrated in FIG. 10, the semiconductor conveyance system 200 includes a plurality of the storage shelves 101 suspended from a ceiling C, a distribution panel 102 configured to feed electric power to the storage shelf 101 via power feed wiring 106, a monitoring stand 104 configured to monitor oxygen concentration in a plant, and a main pipe 108 laid on the ceiling C and configured to feed purge gas to each of the storage shelves 101. The main pipe 108 is further provided with a flow rate controller 130 configured to control a flow rate of purge gas flowing through the main pipe 108. Purge gas adjusted to a desired flow rate or pressure is fed to the main pipe 108. The distribution panel 102 and the monitoring stand 104 are installed, for example, on a floor 109. The distribution panel 102 may be provided with an emergency stop button 102a to stop the feed of the purge gas to the storage shelf 101 in an emergency or other circumstances. The monitoring stand 104 is provided with an oxygen concentration sensor 104a. The monitoring stand 104 may be provided with an emergency stop button 104b to stop the feed of purge gas in an event of a drop in oxygen concentration or other circumstances.

As illustrated in FIGS. 10 and 11, the storage shelf 101 includes, for example, two base frames 110 suspended from the ceiling C and two beam members 114 bridged over the two base frames 110. Each of the base frames 110 includes, for example, two suspension sections 111 that are suspended from the ceiling C and extend in the Z direction that is a vertical direction, and one supporting section 112 that is bridged over lower ends of the suspension sections 111 and extends in the Y direction that is a horizontal direction. The beam members 114 are bridged over the two base frames 110 by being attached to undersides of the two supporting sections 112, which are spaced apart in the X direction, for example.

In the purge system applied to the storage shelf 101, a similar configuration to that illustrated in FIG. 5 is provided, and the valves are controlled to open and close by the controller. The controller controls the flow rate controller 130 based on the open/close states of all the open/close valves provided for the main pipe 108. For the storage shelves 101, the purge system can also perform the individual control of the purge gas feed rate for each of the nozzles 121 of the corresponding placing section 107.

Example embodiments of the present invention have been described as above. However, the present invention is not limited thereto. For example, a type of the open/close valve is not limited to solenoid valves. For example, other types of open/close valves, such as pneumatic actuated valves, may be used.

In the various example embodiments and the modifications described above, an example configuration in which the purge system includes the MFC 35 as a feed controller is described. The purge system may include a pressure controller instead of a flow rate controller. The pressure controller as a feed controller is connected to each of the main pipes 13 and configured to control the pressure of purge gas flowing through the main pipe 13. The pressure controller includes a pressure gauge and a pressure adjustment mechanism provided in the main pipe 13, and the like. In particular, in a case where an orifice is provided in each feed path, pressure of purge gas in each feed path is controlled, and thus individual control of purge gas feed rate can be performed for each nozzle.

Orifices may be omitted in the feed tubes of some or all of the feed paths. By adjusting a pipe diameter or by other operations, purge gas can be fed at a predetermined flow rate in the feed tube of each feed path.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-6. (canceled)

7: A purge system comprising:
a plurality of placing sections;
a plurality of nozzles each configured to feed purge gas to a container at each of the placing sections;
a main pipe through which purge gas flows;
a feed controller connected to the main pipe and configured to control a flow rate or a pressure of the purge gas flowing through the main pipe;
a plurality of feed paths each provided between a respective one of the plurality of placing sections and the main pipe, the plurality of feed paths each including at least one feed tube, all of the feed tubes of the feed paths being connected to the plurality of nozzles;
at least one open/close valve correspondingly provided to each of the placing sections and configured to switch flow of the purge gas in the feed paths; and
a controller configured to control an open/close state of the at least one open/close valve and control the feed controller based on open/close states of all the open/close valves provided to the main pipe; wherein
the controller is further configured to adjust the flow rate of the purge gas supplied to the plurality of nozzles at each of the placing sections to a selected one among multiple predefined supply flow rates.

8: The purge system according to claim 7, wherein the at least one feed tube is provided with an orifice.

9: The purge system according to claim 8, wherein in at least one of the plurality of feed paths, the at least one feed tube includes a plurality of branch tubes connected in parallel, and each of the plurality of branch tubes includes the orifice.

10: The purge system according to claim 8, wherein orifices identical to the orifice are provided for all of the feed tubes of the plurality of feed paths.

11: The purge system according to claim 8, wherein
the plurality of feed paths include a first feed path and a second feed path; and
a first orifice provided in at least one first feed tube serving as the feed tube of the first feed path and a second orifice provided in at least one second feed tube serving as the feed tube of the second feed path are different from each other, so that a flow rate of the purge gas flowing through the first feed tube is different from a flow rate of the purge gas flowing through the second feed tube.

12: The purge system according to claim 7, wherein the feed controller is a flow rate controller configured to control the flow rate of the purge gas flowing through the main pipe.
